(19) United States
(12) Patent Application Publication
(10) Pub. No.: US 2012/0104559 A1
(43) Pub. Date: May 3, 2012

(54) Semiconductor Device Having Island Type Support Patterns

(75) Inventor: Hyun-Chul Kim, Seoul (KR)

(73) Assignee: SAMSUNG ELECTRONICS CO., LTD., Suwon-si (KR)

(21) Appl. No.: 13/238,408

(22) Filed: Sep. 21, 2011

(30) Foreign Application Priority Data
Oct. 29, 2010 (KR) 10-2010-0107011

(51) Int. Cl. H01L 29/06

(52) U.S. Cl. 257/618; 257/E29.005

(57) ABSTRACT

A semiconductor device includes a plurality of cylindrical structures arranged in a first direction and a second direction, and a plurality of unit regions formed in the first direction and the second direction, each of the plurality of unit regions including an island type support pattern supporting the plurality of cylindrical structures contacting side surfaces of the plurality of cylindrical structures and an open region exposing the side surfaces of the plurality of cylindrical structures.

### CROSS-REFERENCE TO RELATED APPLICATIONS

This application claims priority under 35 U.S.C. §119 to Korean Patent Application No. 10-2010-0107011, filed on Oct. 29, 2010, in the Korean Intellectual Property Office (KIPO), the disclosure of which is incorporated herein in its entirety by reference.

### BACKGROUND

1. Field

The inventive concepts relate to a semiconductor device, and more particularly, to a semiconductor device in which structures having a large aspect ratio are prevented or inhibited from collapsing.

2. Description of the Related Art

As a degree of integration increases in semiconductor devices such as dynamic random access memories (DRAMs), a space taken by a semiconductor device decreases while maintaining or increasing a necessary capacitance. To this end, lower electrodes are formed to be cylindrical.

An aspect ratio of a cylindrical lower electrode increases much according to a required capacitance. As a result, the cylindrical lower electrode may collapse or be broken before deposition of a dielectric layer.

### SUMMARY

The inventive concepts provide a semiconductor device in which structures having a high aspect ratio are stably located.

The inventive concepts provide a semiconductor device in which lower electrodes having a high aspect ratio are stable and a subsequent process may be easily performed.

In accordance with an example embodiment of the inventive concepts, a semiconductor device may include a plurality of cylindrical structures arranged in a first direction and a second direction, and a plurality of island type support patterns supporting the plurality of cylindrical structures. In this example embodiment, each island type support pattern contacts side surfaces of the plurality of cylindrical structures, and each of the island type support patterns are separated from each other by an open region.

In accordance with another example embodiment of the inventive concepts, a semiconductor device may include a plurality of cylindrical lower electrodes arranged in a first direction and a second direction. In this example embodiment, the plurality of cylindrical lower electrodes may be separated at an interval of a first pitch in the first direction and a second pitch in the second direction. In this example embodiment, a plurality of unit regions may be formed in the first direction and the second direction and each of the plurality of unit regions may comprise an island type support pattern supporting the plurality of cylindrical structures. In this example embodiment, each of the plurality of unit regions may also include an open region. In this example embodiment, the island type support pattern may contact side surfaces of the plurality of cylindrical structures and the open region may expose side surfaces of the plurality of cylindrical structures. In this example embodiment, the island type support pattern may have a shape with a dimension of n times the first pitch in the first direction and m times the second pitch in the second direction, where n and m are natural numbers, and when the unit region is assumed to be a planar area, a rate of the open region satisfies an expression that 1−(n×m)/(N×M)) and the rate of the open region is 40% or higher.

In accordance with another example embodiment of the inventive concepts, a semiconductor device may include a plurality of groups of electrodes and a plurality of island type supports. In this example embodiment, each island type support may commonly support a group of the electrodes. In this example embodiment, each of the electrodes may be separated from each other by a first pitch in a first direction and a second pitch in a second direction, and each common island type support may be separated from each other by a distance of about the first pitch in the first direction and a distance of about the second pitch in the second direction.

According to an aspect of the inventive concepts, there is provided a semiconductor device including a plurality of cylindrical structures repeatedly arranged in a first direction and a second direction, and a plurality of unit regions repeatedly formed in the first direction and the second direction, each of the plurality of unit regions including an island type support pattern supporting the plurality of cylindrical structures contacting side surfaces of the plurality of cylindrical structures and an open region exposing the side surfaces of the plurality of cylindrical structures.

The plurality of cylindrical structures may be arranged by being separated at an interval of a first pitch in the first direction and a second pitch in the second direction, and the island type support pattern may have a shape with a dimension of n times of the first pitch in the first direction and m times of the second pitch in the second direction, where n and m each are 2 or 3.

The plurality of cylindrical structures may be arranged by being separated at an interval of a first pitch in the first direction and a second pitch in the second direction, and the island type support pattern may have a shape with a dimension of two times of the first pitch in the first direction and m times of the second pitch in the second direction, where m is any one of 2 to 9.

The plurality of cylindrical structures may be arranged by being separated at an interval of a first pitch in the first direction and a second pitch in the second direction, and the island type support pattern may have a shape with a dimension of three times of the first pitch in the first direction and three or four times of the second pitch in the second direction.

The unit regions may be rotated at an angle formed by the first direction and the second direction. The first direction and the second direction may form a right angle and the plurality of cylindrical structures may be arranged at a right angle.

The first direction and the second direction may form an acute angle and the plurality of cylindrical structures may be arranged at an acute angle with respect to the first direction or the second direction. The island type support pattern may be formed at the same height as the top surfaces of the cylindrical structures or at a height lower than the top surfaces of the cylindrical structures.

When the unit region is assumed to be a planar area, a rate of the open region to an area of the unit region may be 40%-50%.

According to another aspect of the inventive concepts, there is provided a semiconductor device including a plurality of cylindrical lower electrodes repeatedly arranged in a first direction and a second direction, and arranged by being separated at an interval of a first pitch in the first direction and a second pitch in the second direction, and a plurality of unit regions repeatedly formed in the first direction and the second direction, each of the plurality of unit regions including an island type support pattern supporting the plurality of cylindrical structures contacting side surfaces of the plurality of cylindrical structures and an open region exposing the side surfaces of the plurality of cylindrical structures, wherein the island type support pattern has a shape with a dimension of n times, where n is a natural number, of the first pitch in the first direction and m times, where m is a natural number, of the second pitch in the second direction, and when the unit region is assumed to be a planar area, a rate of the open region satisfies an expression that 1−(n×m)/(N×M)) and the rate of the open region is 40% or higher.

Any one of n and m may be 2 and the other one may be one of 2-9. Any one of n and m may be 3 and the other one may be 3 or 4. A dielectric layer may be formed on inner and side surfaces of the cylindrical lower electrodes and an upper electrode may be formed on the dielectric layer.

The first direction and the second direction may be arranged at a right angle or an acute angle. The island type support pattern may be formed at the same height as the top surfaces of the cylindrical lower electrodes or at a height lower than the top surfaces of the cylindrical lower electrodes.

According to another aspect of the inventive concepts, there is provided a semiconductor device including a semiconductor substrate including a memory cell region, a plurality of cylindrical lower electrodes repeatedly arranged in a first direction and a second direction in the memory cell region of the semiconductor substrate, and a plurality of unit regions repeatedly formed in the first direction and the second direction, each of the plurality of unit regions including an island type support pattern supporting the plurality of cylindrical structures contacting side surfaces of the plurality of cylindrical structures and an open region exposing the side surfaces of the plurality of cylindrical structures.

The plurality of cylindrical lower electrodes may be arranged by being separated at an interval of a first pitch in the first direction and a second pitch in the second direction, and the island type support pattern may have a shape with a dimension of n times of the first pitch in the first direction and m times of the second pitch in the second direction, where any one of n and m is 2 and the other one is one of 2-9.

The plurality of cylindrical lower electrodes may be arranged by being separated at an interval of a first pitch in the first direction and a second pitch in the second direction, and the island type support pattern may have a shape with a dimension of n times of the first pitch in the first direction and m times of the second pitch in the second direction, where any one of n and m is 3 and the other one is 3 or 4.

A dielectric layer may be formed on inner and side surfaces of the cylindrical lower electrodes and an upper electrode may be formed on the dielectric layer.

The first direction and the second direction may be arranged at a right angle or an acute angle, and the island type support pattern may be formed at the same height as the top surfaces of the cylindrical lower electrodes or at a height lower than the top surfaces of the cylindrical lower electrodes.

### BRIEF DESCRIPTION OF THE DRAWINGS

Example embodiments of the inventive concepts will be more clearly understood from the following detailed description taken in conjunction with the accompanying drawings in which:

FIG. 1 is a plan view schematically illustrating an arrangement of pillar type structures and island type support patterns supporting the pillar type structures in a semiconductor device according to an example embodiment of the inventive concepts;

FIG. 2 is a cross-sectional view of the semiconductor device, taken along line II-II′ of FIG. 1;

FIGS. 3-14 are enlarged plan views schematically illustrating a part of a layout of cylindrical lower electrodes and island type support patterns supporting the cylindrical lower electrodes in a semiconductor device according to an example embodiment of the inventive concepts;

FIG. 15 is a graph showing rates of the open regions for layouts of island type support patterns in semiconductor devices according to an example embodiment of the inventive concepts;

FIGS. 16-22 are cross-sectional views, taken along line a-a′ of FIG. 3, illustrating the operations of a method of manufacturing a semiconductor device according to an example embodiment of the inventive concepts;

FIG. 23 is a plan view of a memory module including a semiconductor memory device according to a technical concept of the present inventive concepts;

FIG. 24 is a schematic block diagram of a memory card including a semiconductor memory device according to a technical concept of the inventive concepts; and

FIG. 25 is a schematic block diagram of a system including a semiconductor memory device according to a technical concept of the inventive concepts.

### DETAILED DESCRIPTION OF THE EMBODIMENTS

Example embodiments are provided to further completely explain the inventive concepts to one skilled in the art to which the example embodiments pertain. However, the inventive concepts are not limited thereto and it will be understood that various changes in form and details may be made therein without departing from the spirit and scope of the following claims. That is, descriptions on particular structures or functions may be presented merely for explaining example embodiments of the inventive concepts.

In the following description, when a layer is described to exist on another layer, the layer may exist directly on the other layer or a third layer may be interposed therebetween. Also, the thickness or size of each layer illustrated in the drawings is exaggerated for convenience of explanation and clarity. Like references indicate like constituent elements in the drawings. As used in the present specification, the term “and/or” includes any one of listed items and all of at least one combination of the items.

The terms used in the present specification are used for explaining a specific example embodiment, not limiting the present inventive concepts. Thus, the expression of singularity in the present specification includes the expression of plurality unless clearly specified otherwise in context. Also, the terms such as “comprise” and/or “comprising” may be construed to denote a certain characteristic, number, step, operation, constituent element, or a combination thereof, but may not be construed to exclude the existence of or a possibility of addition of one or more other characteristics, numbers, steps, operations, constituent elements, or combinations thereof.

In the present specification, the terms such as “first” and “second” are used herein merely to describe a variety of members, parts, areas, layers, and/or portions, but the constituent elements are not limited by the terms. It is obvious that the members, parts, areas, layers, and/or portions are not limited by the terms. The terms are used only for the purpose of distinguishing one constituent element from another constituent element. Thus, without departing from the right scope of the inventive concepts, a first member, part, area, layer, or portion may refer to a second member, part, area, layer, or portion.

Hereinafter, the example embodiments of the inventive concepts are described in detail with reference to the accompanying drawings. In the drawings, the illustrated shapes may be modified according to, for example, manufacturing technology and/or tolerance. Thus, the example embodiments of the inventive concepts may not be construed to be limited to a particular shape of a part described in the present specification and may include a change in the shape generated during manufacturing, for example.

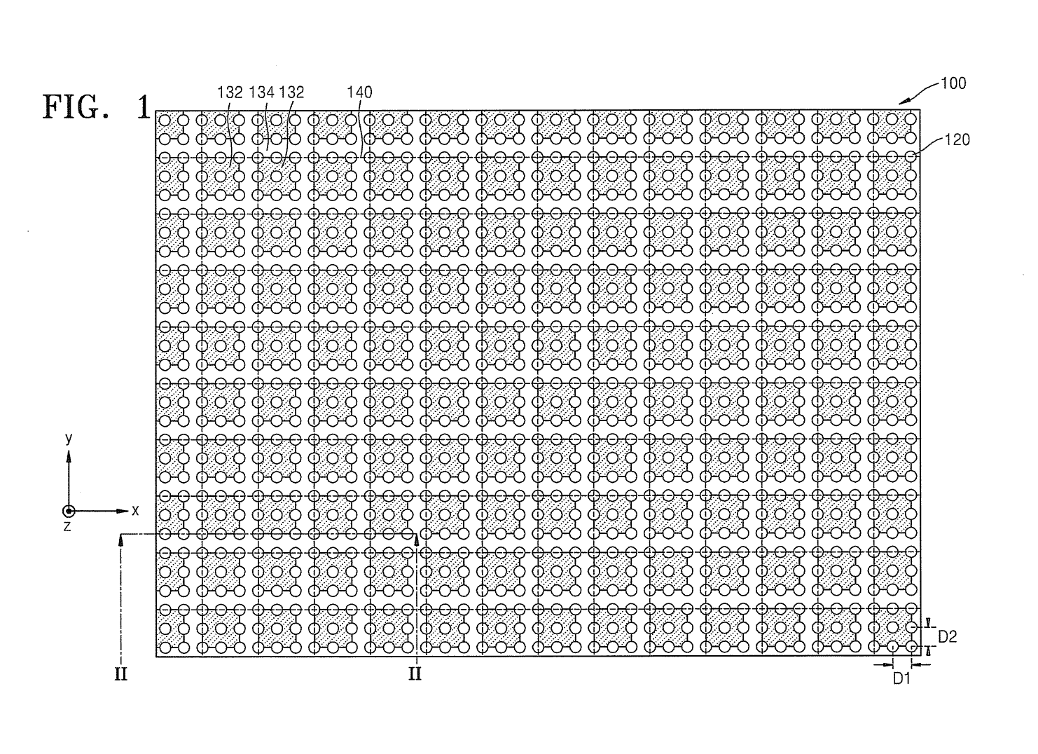

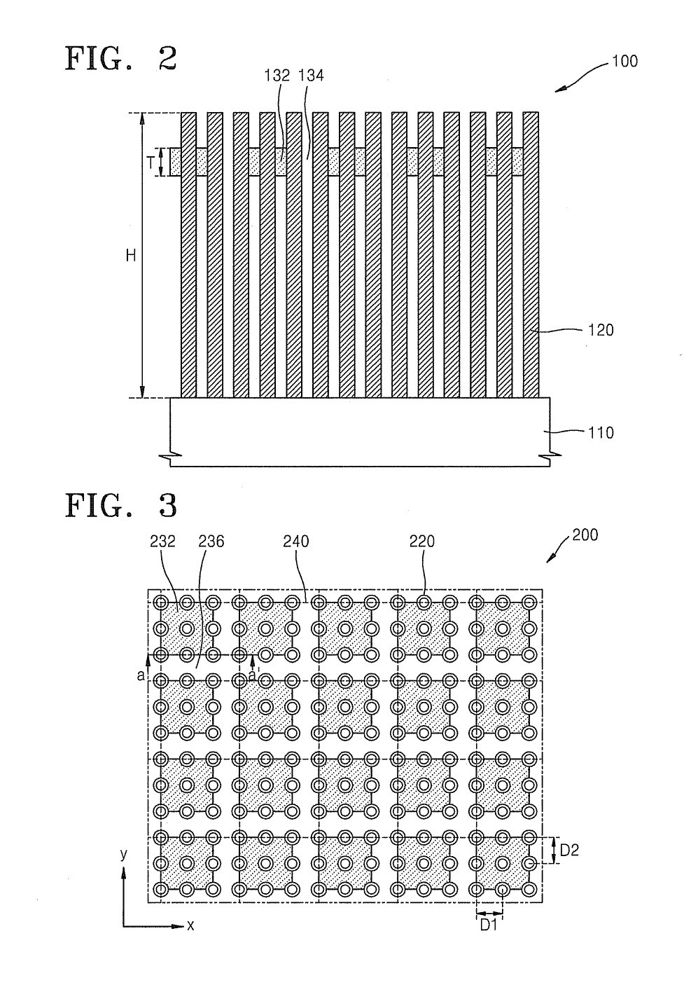

FIG. 1 is a plan view schematically illustrating an arrangement of pillar type structures and island type support patterns supporting the pillar type structures in a semiconductor device 100 according to an example embodiment of the inventive concepts. FIG. 2 is a cross-sectional view of the semiconductor device 100, taken along line II-II′ of FIG. 1.

Referring to FIGS. 1 and 2, the semiconductor device 100 includes a substrate 110 and a plurality of pillar type structures 120. The pillar type structures 120 may be cylindrical structures, however, example embodiments are not limited thereto. For example, the pillar type structures 120 may be polygonal shaped, for example, square or hexagonal. In addition, the invention is not limited to the pillar type structures 120 may be longitudinally extending structures.

The substrate 110 may be, for example, a silicon substrate, a silicon on insulator (SOI) substrate, a silicon germanium substrate, a gallium-arsenic substrate, a ceramic substrate, a quartz substrate, or a display substrate for display. Unit devices (not shown), for example, various types of active devices or passive devices, needed for forming a semiconductor device, may be formed in the substrate 110. The unit devices may be cell transistors such as dynamic random access memory (DRAM) flash memories.

Device isolation layers (not shown) for isolating the unit devices may be formed on the substrate 110. An interlayer insulation layer (not shown) covering the unit devices may be formed on the substrate 110. Also, conductive regions (not shown) electrically connected to the unit devices through the interlayer insulation layer may be formed on the substrate 110. Also, conductive lines (not shown) for connecting the unit devices or the conductive regions may be formed on the substrate 110.

The pillar type structures 120, as illustrated in FIG. 1, may be repeatedly arranged on the substrate 110 in a first direction, for example, a direction x, and a second direction, for example, a direction y. As illustrated in FIG. 1, the pillar type structures 120 may be separated from each other at a first pitch D1 in the direction x and a second pitch D2 in the direction y. Although in FIG. 1 the first pitch D1 is illustrated to be substantially the same as the second pitch D2, the inventive concepts are not limited thereto.

The pillar type structures 120 may be arranged in a number that is greater than or less than the number illustrated in FIG. 1. For example, when the pillar type structures 120 is a lower electrode of a cell capacitor of a DRAM, over several millions of the pillar type structures 120 may be densely arranged on the substrate 110.

A bottom surface of each of the pillar type structures 120 is fixed to the substrate 110. Each of the pillar type structure 120 may have a thin and long shape extending in a direction, for example, a direction z, which is perpendicular to the first direction and the second direction. An aspect ratio, that is, a ratio of width to height, of each of the pillar type structures 120 may belong to a range from about 8 to about 30, for example, 20. For example, the width of each of the pillar type structures 120 may belong to a range from about 30 nm to about 100 nm, for example, about 60 nm. The height H of each of the pillar type structures 120 may belong to a range from about 500 nm to about 4000 nm, for example, about 600 nm.

The pillar type structures 120 each may be, for example, a lower electrode of a cell capacitor of a DRAM. The pillar type structures 120 may have a cylindrical shape and thus may be cylindrical structures. The cylindrical structures may be cylindrical lower electrodes. The pillar type structures 120 may be connected to a source/drain region (not shown) of a DRAM memory cell transistor (not shown) formed in the substrate 110, via a capacitor contact plug (not shown), for example. However, the inventive concepts are not limited to the lower electrode of a cell capacitor of a DRAM only, and may be applied to structures having a high aspect ratio and repeatedly arranged.

The pillar type structures 120 having a high aspect ratio may not vertically stand alone, may not be significantly inclined toward a neighbouring pillar type structures 120, and may not be broken. As shown in FIG. 2, an island type support pattern 132 for supporting the pillar type structures 120 to vertically stand being separated from each other may be provided. The island type support pattern 132 signifies a pattern that is not connected to each other. Thus, the island type support pattern resembles an island. The island type support pattern 132 may support the pillar type structures 120 by at least partially contacting side surfaces of the pillar type structures 120. The island type support pattern 132 may be arranged parallel to the substrate 110 at a predetermined height lower than the top surfaces of the pillar type structures 120 as shown in FIG. 2. In addition, unlike FIG. 2, the island type support pattern 132 may be arranged at the same height as the top surfaces of pillar type structures 120.

A level or layer where the island type support pattern 132 is formed may include a plurality of unit regions 140 that are repeatedly faulted on a planar area in the first direction and the second direction. The island type support pattern 132 signifies a pattern that is formed in each unit region and is not connected to each other, like an island. The unit regions 140 may be arranged in the first direction and the second direction.

As described above, each of the unit regions 140 may include the island type support pattern 132 for supporting the pillar type structures 120. Accordingly, each of the unit regions 140 may include an open region 134 that exposes a side surface of each of the pillar type structures 120. As shown in FIG. 1, the open region 134 may be “L-shaped.” Since the island type support pattern 132 is formed like an island, generation of cracks on the level of the island type support pattern 132 may be fundamentally prevented or reduced.

While the open region 134 is formed on the level of the island type support pattern 132, a portion under the island type support pattern 132 is empty as illustrated in FIG. 2. Thus, a subsequent process may be performed with respect to a portion of each of the pillar type structures 120 located under the island type support pattern 132. As an example of the subsequent process, when each of the pillar type structures 120 is a lower electrode of a cell capacitor of a DRAM, as described later, a dielectric layer and an upper electrode may be formed on the surfaces of cylindrical structures.

As described with reference to FIG. 2, the island type support pattern 132 may be arranged at a height lower than the top surfaces of the pillar type structures 120. In this example embodiment, the height may or may not be predetermined. For example, the island type support pattern 132 may be arranged at a height that is about 7/10 or higher than the height H of the pillar type structures 120. Also, the island type support pattern 132 may be arranged in an upper end portion of each of the pillar type structures 120 so that the pillar type structures 120 may not protrude above the island type support pattern 132.

The island type support pattern 132 may have a thickness T that is between about 1/10 to about 2/10 of the height H of the pillar type structures 120. Also, the island type support pattern 132 may include a multiple layers of island type support patterns for supporting the pillar type structures 120. For example, when the island type support pattern includes two layers, a first island type support pattern may be arranged at a height to support a middle portion of the pillar type structures 120, whereas a second island type support pattern may be arranged to support the upper portions of the pillar type structures 120.

As illustrated in FIG. 1, the island type support pattern 132 may be formed in a 3×3 array between the pillar type structures 120. The side surfaces of the nine pillar type structures 120 arranged in a 3×3 array as described above are exposed by the open region 134. The pillar type structures 120 arranged in a 3×3 array signify the nine pillar type structures 120 consisting of three rows in the direction y and three columns in the direction x.

When the pillar type structures 120 are arranged by being separated from each other at an interval of the first pitch D1 in the direction x and the second pitch D2 in the direction y, the island type support pattern 132 may have a shape with a dimension of twice the first pitch (2×D1) in the direction x and twice the second pitch (2×D2) in the direction y. The shape of the island type support pattern 132 of FIG. 1 is a mere example and will be described in detail later.

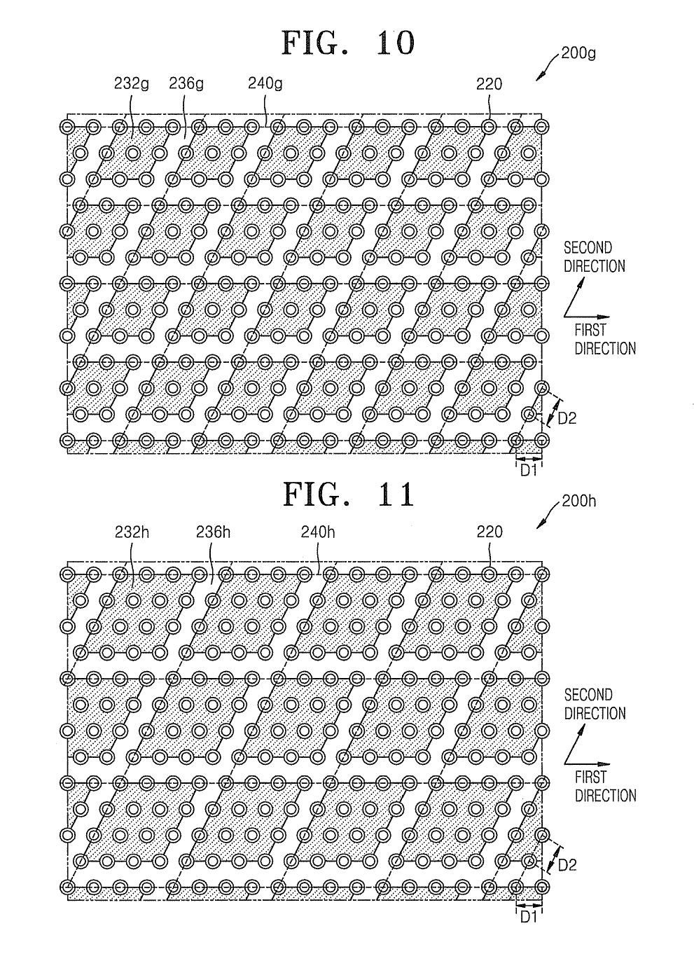

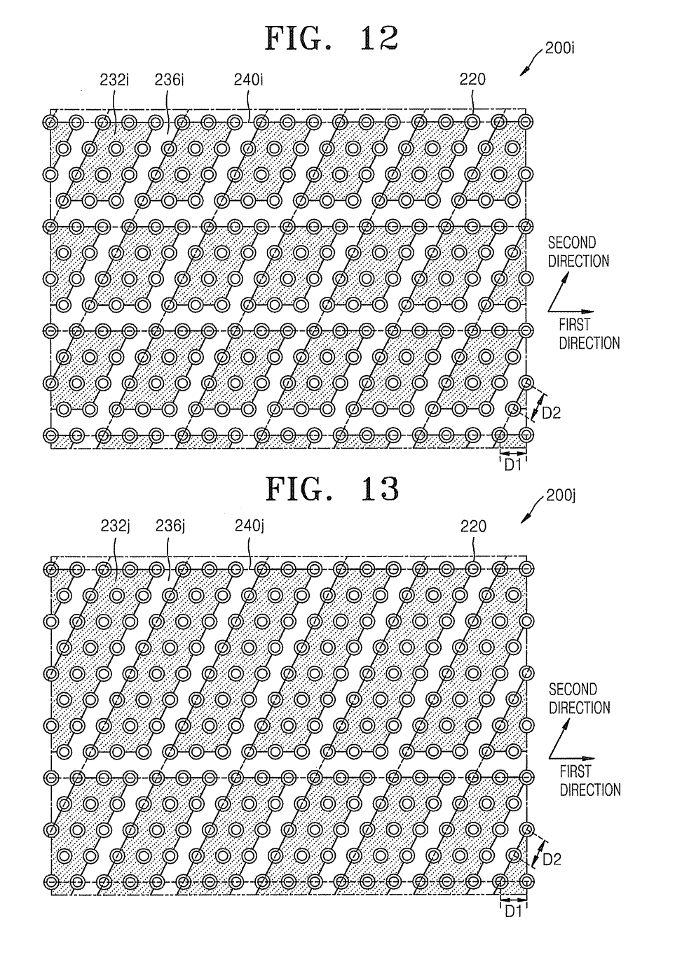

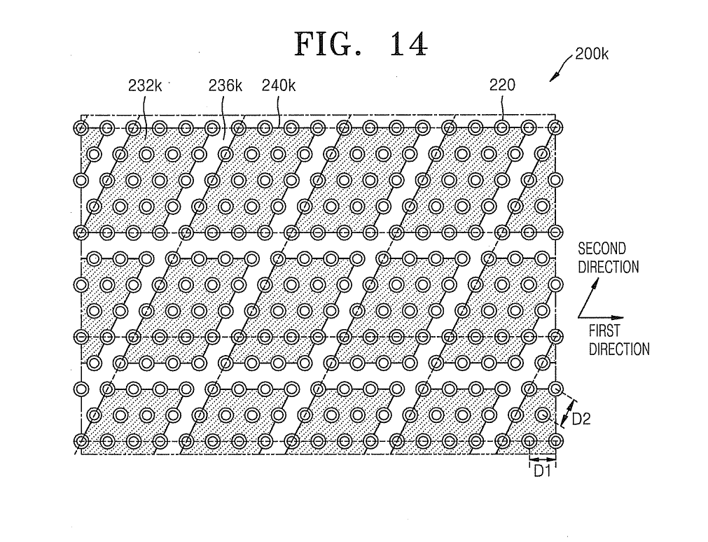

A case in which the pillar type structures 120 of FIG. 1 is a cylindrical structure of a cell transistor of a DRAM, for example, a cylindrical lower electrode, will be described below. FIGS. 3-14 are enlarged plan views schematically illustrating a part of a layout of cylindrical lower electrodes and island type support patterns supporting the cylindrical lower electrodes in a semiconductor device according to example embodiments of the inventive concepts. To clearly understand the technical concepts of the inventive concepts, FIGS. 3-14 illustrate only cylindrical lower electrodes and island type support patterns. Although in FIGS. 3-14 the island type support patterns are described as having a rectangular shape, the island type support patterns may have a hexagonal shape. When the island type support patterns have a rectangular shape, repetitiveness and symmetry are improved so that the island type support patterns may be more stably formed and thus be adopted in the cylindrical structures.

Referring to FIG. 3, a semiconductor device 200 includes a plurality of cylindrical structures, for example, a plurality of cylindrical lower electrodes 220, and island type support patterns 232 for supporting the cylindrical lower electrodes 220.

The cylindrical lower electrodes 220 may be repeatedly arranged in a first direction, for example, a direction x, and a second direction, for example, a direction y, to form in a right angled array of cylindrical lower electrodes 220. The cylindrical lower electrodes 220 may be repeatedly arranged by being separated from each other at an interval of the first pitch D1 in the direction x and the second pitch D2 in the direction y. In FIG. 3, the cylindrical lower electrode 220 are illustrated as two concentric circles in which an inner circle indicates an inner surface of each of the cylindrical lower electrodes 220 and an outer circle indicates an outer surface of each of the cylindrical lower electrode 220. The description on the cylindrical lower electrodes 220 may be identically applied to FIGS. 3-14 and will not be repeated in the following description.

In a level or layer of the island type support patterns 232, a plurality of unit regions 240 are repeatedly formed in the first direction and the second direction. Each of the unit regions 240 includes the island type support pattern 232 and an open region 236. The unit regions 240 are mere regions defined to section a certain space and may be defined different from those shown in FIG. 3. As illustrated in FIG. 3, the unit regions 240 may be arranged in the first direction and the second direction or contact each other.

In the example embodiment of FIG. 3, the island type support patterns 232 are symmetrically formed in the first direction and the second direction. The island type support patterns 232 may be defined to be a region having a square shape with a dimension of twice the first pitch (2×D1; hereinafter, “n×D1” signifies n times of D1) in the direction x and twice the second pitch (2×D2; hereinafter, “m×D2” signifies m times of D2) in the direction y. In this example embodiment, the unit region 240 may be defined as a region having a square shape with a dimension of three times the first pitch (3×D1; hereinafter, “N×D1” signifies N times of D1) in the direction x and three times the second pitch (3×D2, hereinafter, “M×D2” signifies M times of D2) in the direction y. In this case, in the unit region 240, the island type support patterns 232 that at least partially contact the side surfaces of the nine cylindrical lower electrodes 220 at a height may prevent or inhibit the cylindrical lower electrodes 220 from collapsing.

In the example embodiment of FIG. 3, the island type support patterns 232 that are formed twice the first pitch D1 and twice the second pitch D2 may be easily formed without a limit in a photolithography process. In the example embodiment of FIG. 3, when the unit regions 240 are assumed to be a planar area, the ratio of an open region 236 to a unit region 240 (rate of an open region) satisfies an expression that 1−(n×m)/(N×M), where “n,” “m,” “N”, and “M” are natural numbers, and where n may be N−1 and m may be M−1. Since the rate of an open region will be described in the following description, the rate of an open region will not be repeated later.

As described above, in the example embodiment of FIG. 3, “n” and “m” each may be 2 in FIG. 3 and “N” and “M” each may be 3 in FIG. 3. Accordingly, in view of a plane, the rate taken by the open region 236 is 55.6% which is relatively high. Thus, when a dielectric layer is formed on the cylindrical lower electrodes 220, the dielectric layer may be formed more uniformly and symmetrically.

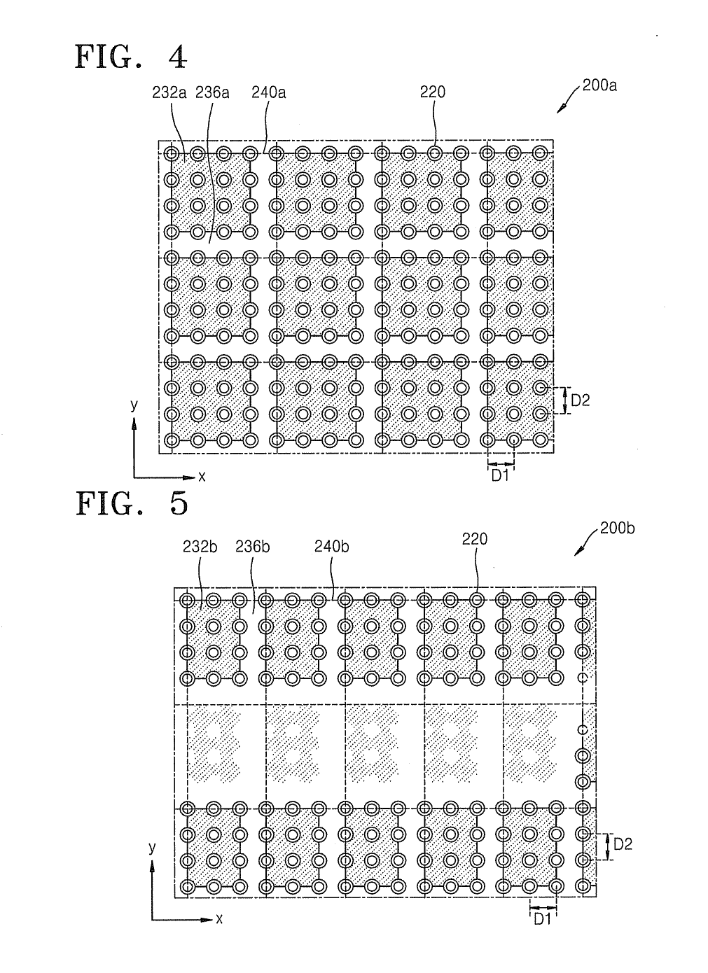

Referring to FIG. 4, a semiconductor device 200a includes the cylindrical lower electrodes 220 and island type support patterns 232a for supporting the cylindrical lower electrodes 220. A level of the island type support patterns 232a includes a plurality of unit regions 240a repeatedly formed in the first direction and the second direction. Each of the unit regions 240a includes the island type support pattern 232a and an open region 236a. The unit regions 240a are mere regions defined to section a certain space and may be defined differently. As illustrated in FIG. 4, the unit regions 240a may be arranged in the first direction and the second direction or contact each other.

In the example embodiment of FIG. 4, the island type support patterns 232a may be defined to be a region having a square shape with a dimension of three times the first pitch (3×D1; hereinafter, “n×D1” signifies n times of D1) in the direction x and three times the second pitch (3×D2; hereinafter, “m×D2” signifies m times of D2) in the direction y. In this example embodiment, the unit region 240a may be defined as a region having a square shape with a dimension of four times the first pitch (4×D1; hereinafter, “N×D1” signifies N times of D1) in the direction x and four times the second pitch (4×D2; hereinafter, “M×D2” signifies M times of D2) in the direction y. In this case, in the unit region 240a, the island type support patterns 232a that at least partially contact the side surfaces of the sixteen cylindrical lower electrodes 220 at a height may prevent or inhibit the cylindrical lower electrodes 220 from collapsing. In FIG. 4, n=3, m=3, N=4, and M=4.

In the example embodiment of FIG. 4, the island type support patterns 232a that are formed three times the first pitch D1 and three times the second pitch D2 may be easily formed without a limit in a photolithography process. In the example embodiment of FIG. 4, when the unit regions 240a are assumed to be a planar area, the rate taken by the open region 236a is calculated by the above expression to be 43.8% which is high. Thus, when a dielectric layer is formed on the cylindrical lower electrodes 220, the dielectric layer may be formed more uniformly and symmetrically.

In summary of FIGS. 3 and 4, the cylindrical lower electrodes 220 are arranged by being separated from each other at an interval of the first pitch D1 in the first direction, for example, the direction x, and the second pitch D2 in the second direction, for example, the direction y. The island type support patterns 232 and 232a have a dimension of n times of the first pitch D1 in the first direction and m times of the second pitch D2 in the second direction, where “n” and “m” each may be 2 or 3.

Referring to FIG. 5, a semiconductor device 200b includes the cylindrical lower electrodes 220 and island type support patterns 232b for supporting the cylindrical lower electrodes 220. A level of the island type support patterns 232b includes a plurality of unit regions 240b repeatedly formed in the first direction and the second direction. Each of the unit regions 240b includes the island type support pattern 232b and an open region 236b. The unit regions 240b are mere regions defined to section a certain space and may be defined differently. As illustrated in FIG. 5, the unit regions 240b may be arranged in the first direction and the second direction or contact each other.

In the example embodiment of FIG. 5, the island type support patterns 232b may be defined to be a region having a rectangular shape with a dimension of twice the first pitch (2×D1; hereinafter, “n×D1” signifies n times of D1) in the direction x and three times the second pitch (3×D2; hereinafter, “m×D2” signifies m times of D2) in the direction y. In this example embodiment, the unit region 240b may be defined as a region having a rectangular shape with a dimension of three times the first pitch (3×D1; hereinafter, “N×D1” signifies N times of D1) in the direction x and four times the second pitch (4×D2; hereinafter, “M×D2” signifies M times of D2) in the direction y. In this case, in the unit region 240b, the island type support patterns 232b that at least partially contact the side surfaces of the twelve cylindrical lower electrodes 220 at a height may prevent or inhibit the cylindrical lower electrodes 220 from collapsing. In FIG. 5, n=2, m=3, N=3, and M=4.

In the example embodiment of FIG. 5, the island type support patterns 232b that are formed twice the first pitch D1 and three times the second pitch D2 may be easily formed without a limit in a photolithography process. In the example embodiment of FIG. 5, when the unit regions 240b are assumed to be a planar area, the rate taken by the open region 236b is calculated by the above expression to be 50% which is high. Thus, when a dielectric layer is formed on the cylindrical lower electrodes 220, the dielectric layer may be formed more uniformly and symmetrically.

In the example embodiment of FIG. 5, as described above, the island type support patterns 232b are defined to be a rectangular region with a dimension of twice the first pitch (2×D1; hereinafter, “n×D1” signifies n times of D1) in the direction x and three times the second pitch (3×D2; hereinafter, “m×D2” signifies m times of D2) in the direction y. However, the island type support patterns 232b may be defined to be a rectangular region with a dimension of twice the first pitch (2×D1; hereinafter, “n×D1” signifies n times of D1) in the direction x and four times the second pitch (4×D2; hereinafter, “m×D2” signifies m times of D2) in the direction y. When the unit regions 240b are assumed to be a planar area, the rate taken by the open region 236b may be calculated by the above expression to be 46.7% when N=3 and M=4.

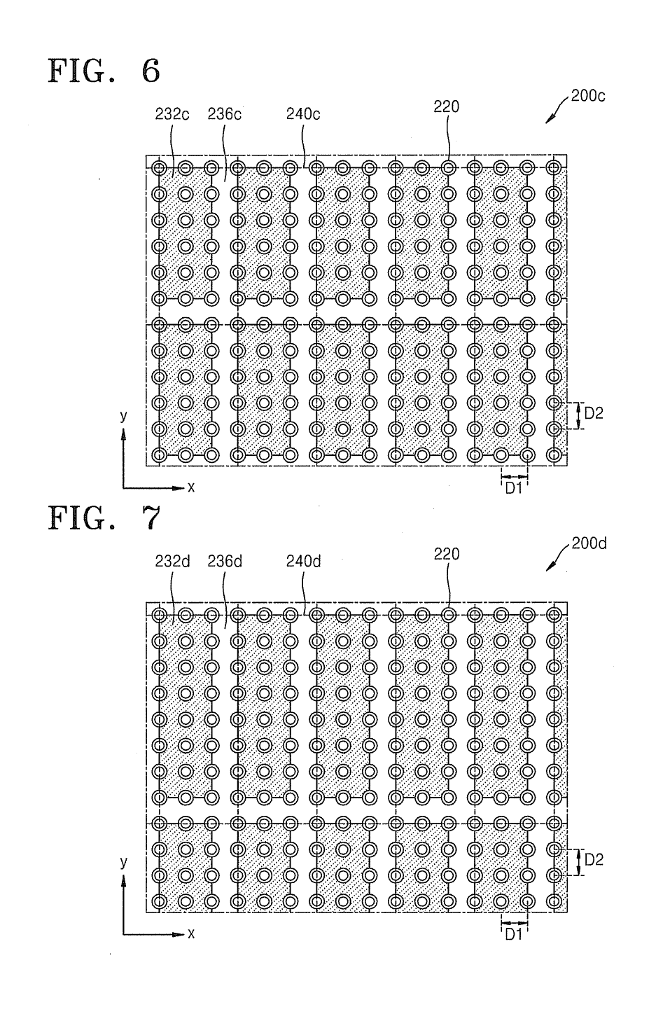

Referring to FIG. 6, a semiconductor device 200c includes the cylindrical lower electrodes 220 and island type support patterns 232c for supporting the cylindrical lower electrodes 220. A level of the island type support patterns 232c includes a plurality of unit regions 240c repeatedly formed in the first direction and the second direction. Each of the unit regions 240c includes the island type support pattern 232c and an open region 236c.

In the example embodiment of FIG. 6, the island type support patterns 232c may be defined to be a region having a rectangular shape with a dimension of twice the first pitch (2×D1; hereinafter, “n×D1” signifies n times of D1) in the direction x and five times the second pitch (5×D2; hereinafter, “m×D2” signifies m times of D2) in the direction y. In this example embodiment, the unit region 240c may be defined as a region having a rectangular shape with a dimension of three times the first pitch (3×D1; hereinafter, “N×D1” signifies N times of D1) in the direction x and six times the second pitch (6×D2; hereinafter, “M×D2” signifies M times of D2) in the direction y. In this case, in the unit region 240c, the island type support patterns 232c that at least partially contact the side surfaces of the eighteen cylindrical lower electrodes 220 at a height may prevent or inhibit the cylindrical lower electrodes 220 from collapsing.

In the example embodiment of FIG. 6, the island type support patterns 232c that are formed twice the first pitch D1 and five times the second pitch D2 may be easily formed without a limit in a photolithography process. In the example embodiment of FIG. 6, when the unit regions 240c are assumed to be a planar area, the rate taken by the open region 236c is calculated by the above expression to be 44.4% which is high. Thus, when a dielectric layer is formed on the cylindrical lower electrodes 220, the dielectric layer may be formed more uniformly and symmetrically.

In the example embodiment of FIG. 6, as described above, the island type support patterns 232c are defined to be a rectangular region with a dimension of twice the first pitch (2×D1; hereinafter, “n×D1” signifies n times of D1) in the direction x and five times the second pitch (5×D2; hereinafter, “m×D2” signifies m times of D2) in the direction y. However, the island type support patterns 232c may be defined to be a rectangular region with a dimension of twice the first pitch (2×D1; hereinafter, “n×D1” signifies n times of D1) in the direction x and six times the second pitch (6×D2; hereinafter, “m×D2” signifies m times of D2) in the direction y. When the unit regions 240c are assumed to be a planar area with N=3 and M=7, the rate taken by the open region 236c may be calculated by the above expression to be 42.9%.

Referring to FIG. 7, a semiconductor device 200d includes the cylindrical lower electrodes 220 and island type support patterns 232d for supporting the cylindrical lower electrodes 220. A level of the island type support patterns 232d includes a plurality of unit regions 240d repeatedly formed in the first direction and the second direction. Each of the unit regions 240d includes the island type support pattern 232d and an open region 236d.

In the example embodiment of FIG. 7, the island type support patterns 232d may be defined to be a region having a rectangular shape with a dimension of twice the first pitch (2×D1; hereinafter, “n×D1” signifies n times of D1) in the direction x and seven times the second pitch (7×D2; hereinafter, “m×D2” signifies m times of D2) in the direction y. In this example embodiment, the unit region 240d may be defined as a region having a rectangular shape with a dimension of three times the first pitch (3×D1; hereinafter, “N×D1” signifies N times of D1) in the direction x and eight times the second pitch (8×D2; hereinafter, “M×D2” signifies M times of D2) in the direction y. In this case, in the unit region 240d, the island type support patterns 232d that at least partially contact the side surfaces of the twenty-four cylindrical lower electrodes 220 at a height may prevent or inhibit the cylindrical lower electrodes 220 from collapsing.

In the example embodiment of FIG. 7, the island type support patterns 232d that are formed twice the first pitch D1 and seven times the second pitch D2 may be easily formed without a limit in a photolithography process. In the example embodiment of FIG. 7, when the unit regions 240d are assumed to be a planar area, the rate taken by the open region 236d is calculated by the above expression to be 41.7% which is high. Thus, when a dielectric layer is formed on the cylindrical lower electrodes 220, the dielectric layer may be formed more uniformly and symmetrically.

In the example embodiment of FIG. 7, as described above, the island type support patterns 232d are defined to be a rectangular region with a dimension of twice the first pitch (2×D1; hereinafter, “n×D1” signifies n times of D1) in the direction x and seven times the second pitch (7×D2; hereinafter, “m×D2” signifies m times of D2) in the direction y. However, the island type support patterns 232d may be defined to be a rectangular region with a dimension of twice the first pitch (2×D1; hereinafter, “n×D1” signifies n times of D1) in the direction x and eight times the second pitch (8×D2; hereinafter, “m×D2” signifies m times of D2) in the direction y. When the unit regions 240d are assumed to be a planar area with N=3 and M=9, the rate taken by the open region 236d may be calculated by the above expression to be 40.7%.

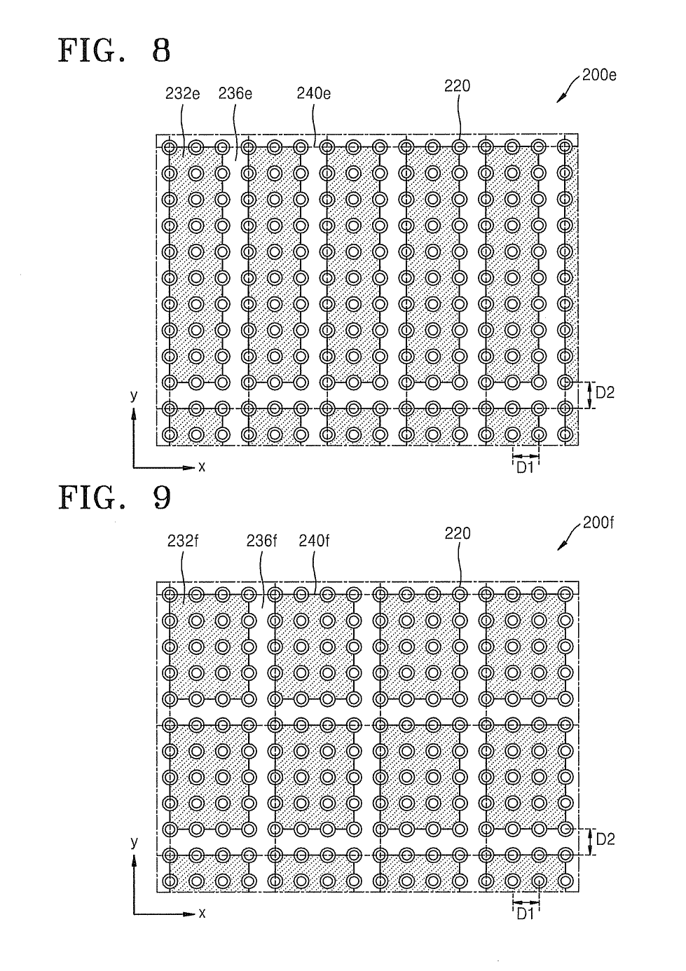

Referring to FIG. 8, a semiconductor device 200e includes the cylindrical lower electrodes 220 and island type support patterns 232e for supporting the cylindrical lower electrodes 220. A level of the island type support patterns 232e includes a plurality of unit regions 240e repeatedly formed in the first direction and the second direction. Each of the unit regions 240e includes the island type support pattern 232e and an open region 236e.

In the example embodiment of FIG. 8, the island type support patterns 232e may be defined to be a region having a rectangular shape with a dimension of twice the first pitch (2×D1; hereinafter, “n×D1” signifies n times of D1) in the direction x and nine times the second pitch (9×D2; hereinafter, “m×D2” signifies m times of D2) in the direction y. In this example embodiment, the unit region 240e may be defined as a region having a rectangular shape with a dimension of three times the first pitch (3×D1; hereinafter, “N×D1” signifies N times of D1) in the direction x and ten times the second pitch (10×D2; hereinafter, “M×D2” signifies M times of D2) in the direction y. In this case, in the unit region 240e, the island type support patterns 232e that at least partially contact the side surfaces of the thirty cylindrical lower electrodes 220 at a height may prevent or inhibit the cylindrical lower electrodes 220 from collapsing.

In the example embodiment of FIG. 8, the island type support patterns 232e that are formed twice the first pitch D1 and nine times the second pitch D2 may be easily formed without a limit in a photolithography process. In the example embodiment of FIG. 8, when the unit regions 240e are assumed to be a planar area, the rate taken by the open region 236e is calculated by the above expression to be 40.0% which is high. Thus, when a dielectric layer is formed on the cylindrical lower electrodes 220, the dielectric layer may be formed more uniformly and symmetrically.

In summary of FIGS. 3 and 5-8, the cylindrical lower electrodes 220 are arranged by being separated from each other at an interval of the first pitch D1 in the first direction, for example, the direction x, and the second pitch D2 in the second direction, for example, the direction y. The island type support patterns 232 and 232b-232e have a dimension of n times of the first pitch D1 in the first direction and m times of the second pitch D2 in the second direction, where “m” may be 2, 3, 5, 7, or 9. Also, as described above, “m” that is a dimension of m times may be 4, 6, or 8. Thus, according to the inventive concepts, “m” may be any one of 2 to 9. On a similar note, the unit regions 240 and 240b-e have a dimension of “N” times of the first pitch D1 in the first direction and “M” times of the second pitch D2 in the second direction, where “M” may be 3, 4, 6, 8, or 10. Also, as described above, “M” may also be 5, 7, or 9. Thus, according to the inventive concepts, “M” may be any one of 3 to 10, though example embodiments are not limited thereto as M may be greater than 10.

Referring to FIG. 9, a semiconductor device 200f includes the cylindrical lower electrodes 220 and island type support patterns 232f for supporting the cylindrical lower electrodes 220. A level of the island type support patterns 232f includes a plurality of unit regions 240f repeatedly formed in the first direction and the second direction. Each of the unit regions 240f includes the island type support pattern 232f and an open region 236f.

In the example embodiment of FIG. 9, the island type support patterns 232f may be defined to be a region having a rectangular shape with a dimension of three times the first pitch (3×D1; hereinafter, “n×D1” signifies n times of D1) in the direction x and four times the second pitch (4×D2; hereinafter, “m×D2” signifies m times of D2) in the direction y. In this example embodiment, the unit region 240f may be defined as a region having a rectangular shape with a dimension of four times the first pitch (4×D1; hereinafter, “N×D1” signifies N times of D1) in the direction x and five times the second pitch (5×D2; hereinafter, “M×D2” signifies M times of D2) in the direction y. In this case, in the unit region 240f, the island type support patterns 232f that at least partially contact the side surfaces of the twenty cylindrical lower electrodes 220 at a height may prevent or inhibit the cylindrical lower electrodes 220 from collapsing.

In the example embodiment of FIG. 9, the island type support patterns 232f that are formed three times the first pitch D1 and four times the second pitch D2 may be easily formed without a limit in a photolithography process. In the example embodiment of FIG. 9, when the unit regions 240f are assumed to be a planar area, the rate taken by the open region 236f is calculated by the above expression to be 40.0% which is high. Thus, when a dielectric layer is formed on the cylindrical lower electrodes 220, the dielectric layer may be formed more uniformly and symmetrically.

In summary of FIGS. 4 and 9, the cylindrical lower electrodes 220 are arranged by being separated from each other at an interval of the first pitch D1 in the first direction, for example, the direction x, and the second pitch D2 in the second direction, for example, the direction y. The island type support patterns 232a and 232f have a dimension of three times of the first pitch D1 in the first direction and three or four times of the second pitch D2 in the second direction.

Also, in summary of FIGS. 3-9, the island type support patterns 232 and 232a-232f have a dimension of n times, where “n” is a natural number, of the first pitch D1 in the first direction and m times, where “m” is a natural number, of the second pitch D2 in the second direction. When the unit regions 240 and 240a-240f are assumed to be a planar area, the rates of the open region 236 and 236a-236f satisfy the expression that 1−(n×m)/(N×M)). The rate of an open region maintains over 40%, for example, between 40% and 56%.

Referring to FIGS. 10-14, semiconductor devices 200g-200k, which are respectively modified examples of the semiconductor devices 200, 200a, 200b, 200d, and 200f of FIGS. 3, 4, 5, 7, and 9, include the cylindrical lower electrodes 220 and island type support patterns 232g-232k for supporting the cylindrical lower electrodes 220.

The cylindrical lower electrodes 220 may be repeatedly arranged in the first direction and second direction. The cylindrical lower electrodes 220 may be arranged by being separated from each other at an interval of the first pitch D1 in the first direction and the second pitch D2 in the second direction. Unit regions 240g-240k are rotated at an angle formed by the first direction and the second direction. Each of the unit regions 240g-240k includes the island type support pattern 232g-232k and an open region 236g-236k. The angle formed by the first direction and the second direction may be an acute angle.

While the cylindrical lower electrodes 220 of the semiconductor devices 200, 200a, 200b, 200d, and 200f of FIGS. 3, 4, 5, 7, and 9 are arranged in a right angle array, the cylindrical lower electrodes 220 of the semiconductor devices 200g-200k of FIGS. 10-14 are arranged in an acute angle array by being inclined at an angle formed by the first direction and the second direction, for example, by an acute angle. Nevertheless, the technical concepts of the inventive concepts may be identically applied to the island type support patterns 232g-232k.

The island type support patterns 232g-232k may correspond to the island type support patterns 232, 232a, 232b, 232d, and 232f, as described above. Although FIGS. 10-14 illustrate modified examples of the semiconductor devices 200, 200a, 200b, 200d, and 200f of FIGS. 3, 4, 5, 7, and 9, the technical concepts of the inventive concepts may be applied to the semiconductor devices 200c and 200e of FIGS. 6 and 8 in the same manner.

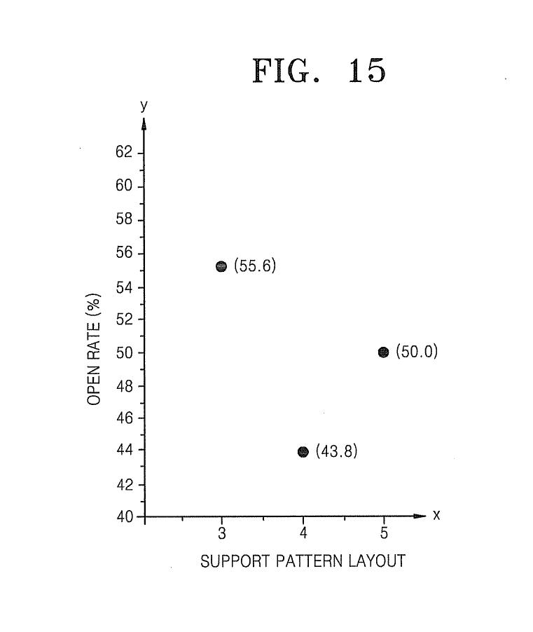

FIG. 15 is a graph showing rates of the open regions for layouts of island type support patterns in semiconductor devices according to example embodiments of the inventive concepts. Referring to FIG. 15, the x axis indicates a layout pattern of the island type support patterns shown in FIGS. 3, 4, and 5, and the y axis indicates a rate of an open region to the whole area of the layout patterns. The layout of FIG. 3 according to an example embodiment of the inventive concepts indicates a rate of an open region to be about 55.6%. The layout of FIG. 4 according to an example embodiment of the inventive concepts indicates a rate of an open region to be about 43.8%. The layout of FIG. 5 according to an example embodiment of the inventive concepts indicates a rate of an open region to be about 50.0%.

When the rate of an open region is small, it is difficult to perforin a subsequent process of forming an upper electrode or a dielectric layer on a surface of a cylindrical lower electrode. When the rate of an open region is small, a subsequent material such as a dielectric layer material is asymmetrically or irregularly deposited so that a subsequent material deposition characteristic may be deteriorated. Thus, the rate of an open region over a certain degree needs to be secured for the subsequent process. The semiconductor devices according to the example embodiments of the inventive concepts secure a rate of an open region over about 40%.

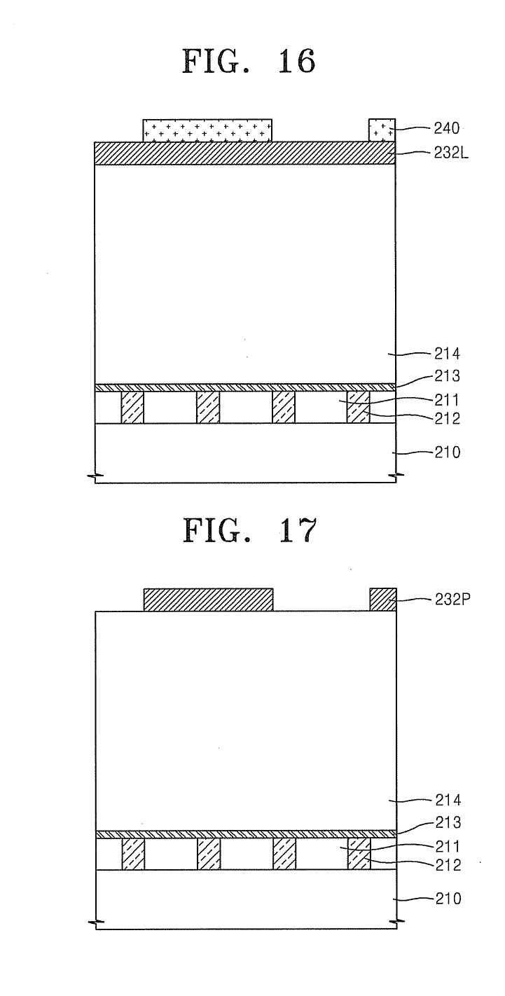

FIGS. 16-22 are cross-sectional views, taken along line a-a′ of FIG. 3, illustrating the operations of a method of manufacturing a semiconductor device according to an example embodiment of the inventive concepts. Although FIGS. 16-22 illustrate a method of manufacturing the semiconductor device 200, the method may be identically applied to processes of manufacturing the semiconductor devices 200a-200k of FIGS. 4-14.

Referring to FIG. 16, an interlayer insulation layer 211, a contact plug 212, and an etch stop layer 213 are formed on a substrate 210 in which a cell region and a dummy region are defined. A first mold layer 214 for forming a capacitor is formed on the etch stop layer 213. A support layer 232L is formed on the first mold layer 214. The support layer 232L may have a thickness of 10 nm to 500 nm.

A mask pattern 240 for pattering the support layer 232L is formed on the support layer 232L. The mask pattern 240 may have a pattern corresponding to the island type support patterns 232 of FIG. 3. The mask pattern 240 may be, for example, a photoresist pattern.

The support layer 232L may be formed of a material having a different etch selectivity from that of the first mold layer 214. For example, when a limulus amoebocyte lysate (LAL) lift-off process is used for removing of the first mold layer 214, the support layer 232L may be formed of a material having a lower etch rate than that of LAL and having a dielectric characteristic.

If the first mold layer 214 is formed of any one of SiO₂, SiGe, and carbon-based material films, the support layer 232L may be formed of any one of SiN, SiCN, TaO, and TiO₂. However, the material of the support layer 232L is not limited to the above materials.

Referring to FIG. 17, the first mold layer 214 is exposed between support layer patterns 232P. For example, the support layer patterns 232P are formed by dry etching the support layer 232L using the mask pattern 240 as an etch mask.

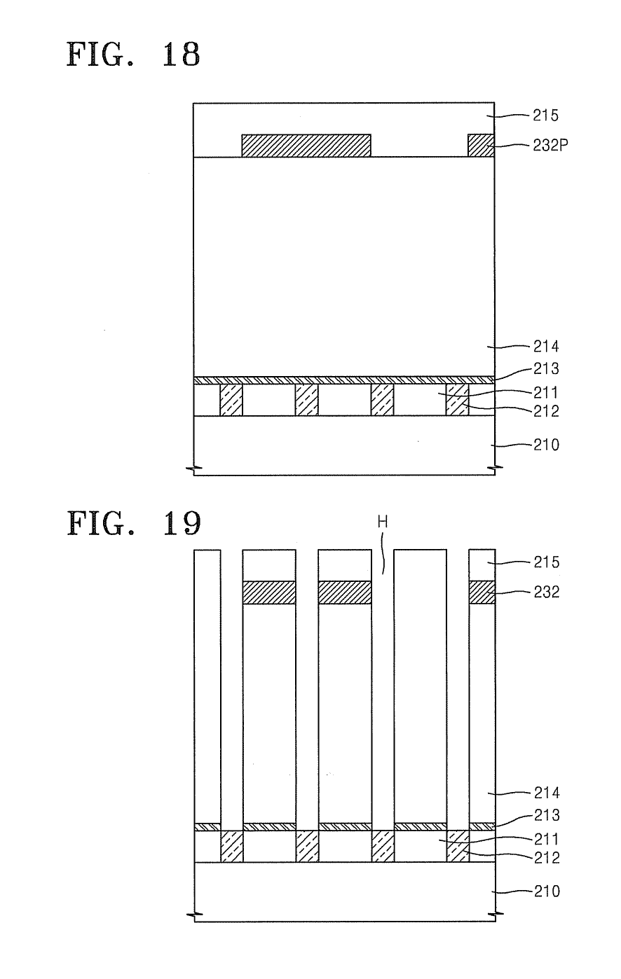

Referring to FIG. 18, a second mold layer 215 is formed on the first mold layer 214 and the support layer pattern 232P. The second mold layer 215 may be formed of the same material as the first mold layer 214 or a material having a similar etch rate to that of the first mold layer 214, for example, a material in which, when the first mold layer 214 and the second mold layer 215 are removed by a LAL lift-off process, a difference between the etch speed of the second mold layer 215 by LAL and the etch rate of the first mold layer 214 is 10% or less. The second mold layer 215 may be formed to have a thickness capable of covering the whole of the support layer patterns 232P, for example, at least 50 nm. Also, a sum of the thicknesses of the first and second mold layers 214 and 215 may be 1000 nm to 4000 nm.

Referring to FIG. 19, a plurality of holes H are formed at positions for forming cylindrical lower electrodes by etching the second mold layer 215, the support layer patterns 232P, the first mold layer 214, and the etch stop layer 213 until the contact plug 212 is exposed. By forming the holes H in the support layer patterns 232P, the support layer patterns 232P may have substantially the same shape as the island type support pattern 232 of FIG. 3.

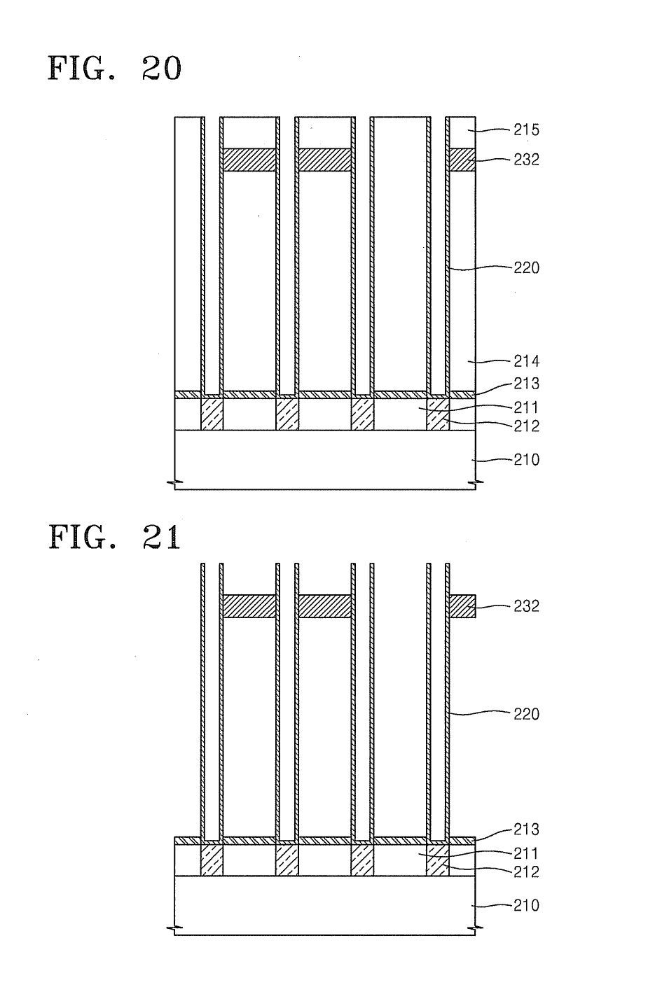

Referring to FIG. 20, after depositing a conductive material on the entire surface of a resultant product of the substrate 210, that is, on the inner walls of the holes H and an upper surface of the second mold layer 215, the conductive material on the inner wall of each of the holes H is separated to thus form the cylindrical lower electrodes 220. The cylindrical lower electrodes 220 are formed by forming a buried layer (not shown) over the entire surface of the resultant product of the substrate 110 to fill the holes H after the conductive material is formed, and performing a planarization process of removing the buried layer and the conductive material until the second mold layer 215 is exposed through etch back and/or a chemical mechanical polishing (CMP) process.

The cylindrical lower electrodes 220 may be formed of, for example, polysilicon or titanium nitride (TiN). The buried layer and the conductive material on the second mold layer 215 may be removed respectively by etch back and CMP process. The buried layer may be formed of the same material as the first mold layer 214 and the second mold layer 215 or a material having a similar etch rate. The buried layer may be, for example, an oxide film.

Referring to FIG. 21, after forming the cylindrical lower electrodes 220, the first mold layer 214 and the second mold layer 215 are removed by wet etch. Also, the buried layer may be removed separately or together with the first mold layer 214 and the second mold layer 215. For example, the first mold layer 214, the second mold layer 215, and the buried layer may be removed by a lift-off process using hydrofluoric acid (HF) or LAL. Thus, as described above, the support layer 232L may have an etch rate lower than that of the first mold layer 214 and the second mold layer 215 with respect to LAL. The cylindrical lower electrodes 220 are supported by the island type support patterns 232 as described above. In FIG. 21, the island type support patterns 232 is formed at a height lower than a surface of a cylindrical structure, that is, the cylindrical lower electrodes 220. However, the island type support patterns 232 may be formed at the same height as the surfaces of the cylindrical lower electrodes 220.

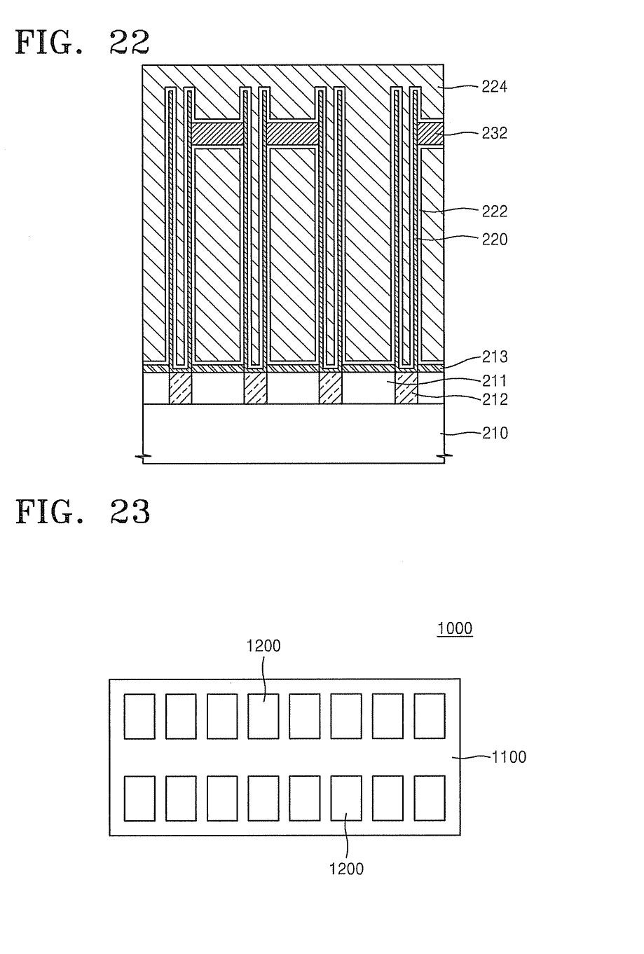

Referring to FIG. 22, after removing the first mold layer 214, the second mold layer 215, and the buried layer, a dielectric layer 222 and an upper electrode 224 are formed on the cylindrical lower electrodes 220 to thus complete a DRAM cell capacitor. A material of the dielectric layer 222 and a material of the upper electrode 224 are uniformly deposited a portion under the support patterns 232 through an open region that is formed over a predetermined rate on a support pattern level.

FIG. 23 is a plan view of a memory module 1000 including a semiconductor memory device according to a technical concept of the inventive concepts. Referring to FIG. 23, the memory module 1000 may include a printed circuit board 1100 and a plurality of semiconductor packages 120.

The semiconductor packages 1200 may include semiconductor memory devices according to example embodiments of the inventive concepts. In particular, the semiconductor packages 1200 may include a characteristic structure of at least one semiconductor device selected from the semiconductor memory devices according to example embodiments of the inventive concepts.

The memory module 1000 according to the present example embodiment may be a single in-line memory module (SIMM) in which a plurality of semiconductor packages 1200 are mounted only on one side of a printed circuit board and a dual in-line memory module (DIMM) in which the semiconductor packages 1200 are mounted on both sides of a printed circuit board. Also, the memory module 1000 according to the present example embodiment may be a fully buffered DIMM (FBDIMM) having an advanced memory buffer (AMB) providing external signals to the semiconductor packages 1200.

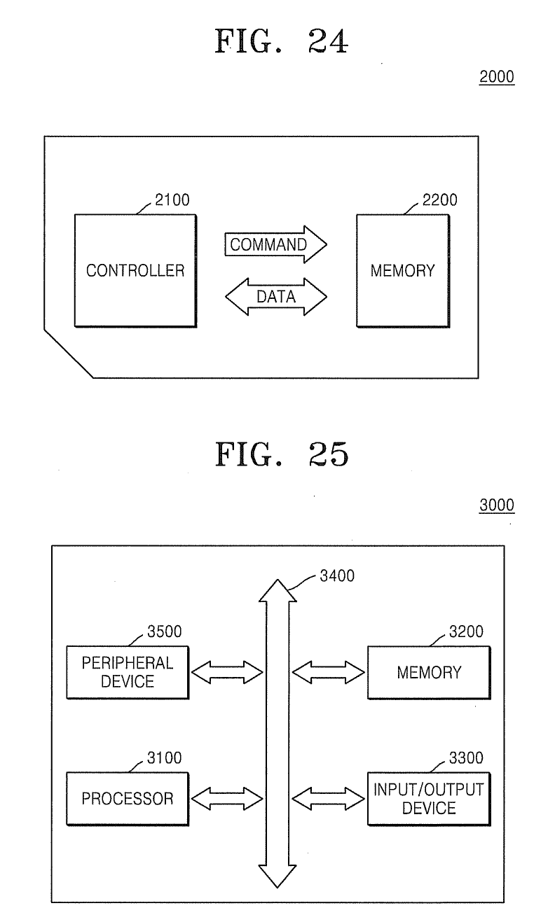

FIG. 24 is a schematic block diagram of a memory card 2000 including a semiconductor memory device according to a technical concept of the inventive concepts. Referring to FIG. 24, the memory card 2000 according to the present example embodiment may include a controller 2100 and a memory 2200 which are arranged to exchange electric signals with each other. For example, when the controller 2100 issues a command, the memory 2200 may transmit data.

The memory 2200 may include a semiconductor memory device according to a technical concept of the inventive concepts. In particular, the memory 2200 may have a characteristic structure of at least one of the above-described semiconductor memory devices according to example embodiment of the inventive concepts.

The memory card 2000 may be one of a variety of memory cards, for example, a memory stick card, a smart media (SM) card, a secure digital (SD) card, a mini-secure digital (SD) card, and a multimedia card (MMC).

FIG. 25 is a schematic block diagram of a system 3000 including a semiconductor memory device according to a technical concept of the inventive concepts. Referring to FIG. 3, in the system 3000, a processor 3100, a memory 3200, and an input/output device 3300 may perform data communication with one another using a bus 3400.

The memory 3200 of the system 3000 may include a random access memory (RAM) and a read only memory (ROM). Also, the system 3000 may include a peripheral device 3500 such as a floppy disk drive and a compact disk (CD) ROM drive.

The memory 3200 may include codes and data for an operation of the processor 3100. The system 3000 may be used for a mobile phone, an MP3 player, a navigation apparatus, a portable multimedia player (PMP), a solid state disk (SSD), or household appliances.

As described above, in a semiconductor device according to the inventive concepts, since the island type support patterns are provided between the cylindrical structures, cracks are fundamentally prevented from being generated in the island type support patterns. Also, an open region may be obtained over a predetermined rate in a unit area of a support pattern level.

Also, in a semiconductor device according to the inventive concepts, since the island type support patterns are provided between the cylindrical structures and simultaneously an open region may be obtained over a predetermined rate in a unit area of a support pattern level, a subsequent material, for example, a dielectric layer, may be symmetrically and uniformly deposited on the cylindrical lower electrodes.

While the inventive concepts have been particularly shown and described with reference to example embodiments thereof, it will be understood that various changes in form and details may be made therein without departing from the spirit and scope of the following claims.

What is claimed is:

1. A semiconductor device comprising:
a plurality of cylindrical structures arranged in a first direction and a second direction; and
a plurality of island type support patterns supporting the plurality of cylindrical structures, each island type support pattern contacting side surfaces of the plurality of cylindrical structures, each of the island type support pattern being separated from each other by an open region.

2. The semiconductor device of claim 1, wherein
the plurality of cylindrical structures are separated at an interval of a first pitch in the first direction and a second pitch in the second direction, and
the island type support patterns have a shape with a dimension of n times of the first pitch in the first direction and m times of the second pitch in the second direction, where n and m each are one of 2 and 3.

3. The semiconductor device of claim 1, wherein
the plurality of cylindrical structures are separated at an interval of a first pitch in the first direction and a second pitch in the second direction, and
the island type support patterns have a shape with a dimension of two times of the first pitch in the first direction and m times of the second pitch in the second direction, where m is one of 2 to 9.

4. The semiconductor device of claim 1, wherein
the plurality of cylindrical structures are separated at an interval of a first pitch in the first direction and a second pitch in the second direction, and
the island type support patterns have a shape with a dimension of three times of the first pitch in the first direction and one of three and four times of the second pitch in the second direction.

5. The semiconductor device of claim 1, wherein the first direction and the second direction form an acute angle.

6. The semiconductor device of claim 1, wherein the first direction and the second direction form a right angle and the plurality of cylindrical structures are arranged at a right angle.

7. The semiconductor device of claim 1, wherein the first direction and the second direction foam an acute angle and the plurality of cylindrical structures are arranged at an acute angle with respect to the first direction or the second direction.

8. The semiconductor device of claim 1, wherein the island type support patterns are at a same height as top surfaces of the cylindrical structures or at a height lower than the top surfaces of the cylindrical structures.

9. The semiconductor device of claim 1, wherein
the plurality of cylindrical structures are separated at an interval of a first pitch in the first direction and a second pitch in the second direction, and
each of the island type support patterns have a shape with a dimension of n times the first pitch in the first direction and m times the second pitch in the second direction,
the island type support patterns are each arranged in a unit region having a dimension N times of the first pitch in the first direction and M times of the second pitch in the second direction, and
a rate of an open region of the unit region is about 40% to about 50%.

10. A semiconductor device comprising:
a plurality of cylindrical lower electrodes arranged in a first direction and a second direction, the plurality of cylindrical lower electrodes being separated at an interval of a first pitch in the first direction and a second pitch in the second direction; and
a plurality of unit regions formed in the first direction and the second direction, each of the plurality of unit regions comprising an island type support pattern supporting the plurality of cylindrical structures and an open region, the island type support pattern contacting side surfaces of the plurality of cylindrical structures, and the open region exposing side surfaces of the plurality of cylindrical structures,
wherein
the island type support pattern has a shape with a dimension of n times the first pitch in the first direction and m times the second pitch in the second direction, where n and m are natural numbers, and when the unit region is assumed to be a planar area, a rate of the open region satisfies an expression that 1−(n×m)/(N×M)) and the rate of the open region is 40% or higher and the unit region has a dimension N times the first pitch in the first direction and M times the second pitch in the second direction.

11. The semiconductor device of claim 10, wherein any one of n and m is 2 and the other one is one of about 2 to about 9.

12. The semiconductor device of claim 10, wherein any one of n and m is 3 and the other one is one of 3 and 4.

13. The semiconductor device of claim 10, wherein a dielectric layer is on inner and side surfaces of the cylindrical lower electrodes and an upper electrode is formed on the dielectric layer.

14. The semiconductor device of claim 10, wherein the first direction and the second direction are arranged at one of a right angle and an acute angle.

15. The semiconductor device of claim 10, wherein the island type support pattern is one of at a same height as top surfaces of the cylindrical lower electrodes and at a height lower than the top surfaces of the cylindrical lower electrodes.

16. A semiconductor device comprising:
a plurality of groups of electrodes; and
a plurality of island type supports, each island type support commonly supporting a group of the electrodes, wherein
each of the electrodes are separated from each other by a first pitch in a first direction and a second pitch in a second direction, and each common island type support is separated from each other by a distance of about the first pitch in the first direction and a distance of about the second pitch in the second direction.

17. The semiconductor device of claim 16, wherein an aspect ratio of each of the electrodes is about 8 to about 30.

18. The semiconductor device of claim 16, wherein the first direction and the second direction are perpendicular to each other.

19. The semiconductor device of claim 16, wherein the first direction and the second direction are skew.

20. The semiconductor device of claim 16, wherein the plurality of island type supports are arranged at one of a first end of the electrodes and nearer one end of the first electrodes than another end of the electrodes.
